(19) United States
(12) Patent Application Publication
(10) Pub. No.: US 2024/0243551 A1
(43) Pub. Date: Jul. 18, 2024

(54) LASER LATERAL CONFINEMENT AND COUPLING STRUCTURE

(71) Applicant: BOARD OF REGENTS, THE UNIVERSITY OF TEXAS SYSTEM, Austin, TX (US)

(72) Inventors: Weidong Zhou, Southlake, TX (US); Mingsen Pan, Arlington, TX (US)

(21) Appl. No.: 18/412,144

(22) Filed: Jan. 12, 2024

Related U.S. Application Data
(60) Provisional application No. 63/438,841, filed on Jan. 13, 2023.

(51) Int. Cl. H01S 5/183; H01S 5/11; H01S 5/343

(52) U.S. Cl. CPC H01S 5/18319; H01S 5/11; H01S 5/18361; H01S 5/3432

(57) ABSTRACT

An apparatus for a photonic crystal surface emitting laser (PCSEL) device includes a PC cavity comprising a photonic crystal (PC) lattice comprising first nanoholes in a core region of the PC cavity, a plurality of lateral distributed Bragg reflector gratings (DBRs) that are truncated around the PC lattice, and opening regions between adjacent and truncated lateral DBRs around the PC lattice. The PCSEL devise also includes a multiple quantum well (MQW) layer coupled to the PC cavity in a vertical direction. The PCSEL device is configured to emit light in the vertical direction.

### CROSS-REFERENCE TO RELATED APPLICATIONS

The present application claims priority to U.S. Provisional Patent Application No. 63/438,841, which was filed Jan. 13, 2023, is titled “Laser Lateral Confinement and Coupling Structure,” and is hereby incorporated herein by reference in its entirety.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Current laser technologies can have limited output optical power and operation speed to maintain certain high optical beam quality. Operation speed relates to the switching time of the laser device to achieve lasing and emit light, for instance to achieve a data transmission speed or rate in laser based emitters. For example, current laser technologies rely on trade-offs and more complicated optical lens systems to provide higher optical power, operation speed, and optical beam quality, which also increases manufacturing cost and reduces reliability.

### SUMMARY

In accordance with at least one example of the disclosure, an apparatus for a photonic crystal surface emitting laser (PCSEL) device contains a photonic crystal (PC) cavity including a PC lattice comprising first nanoholes in a core region of the PC cavity, a plurality of lateral distributed Bragg reflector gratings (DBRs) that are truncated around the PC lattice, and opening regions between adjacent and truncated lateral DBRs around the PC lattice. The apparatus also contains a multiple quantum well (MQW) layer coupled to the PC cavity in a vertical direction. The PCSEL device is configured to emit light in the vertical direction.

In examples, the lateral DBRs comprise a same number of DBRs and increasing the number of DBRs increases lateral optical confinement in the PC cavity.

In examples, increasing the lateral optical confinement by the lateral DBRs in the PC cavity also increases emission speed and beam output power in the vertical direction of the PC cavity.

In examples, the adjacent and truncated lateral DBRs also form corners around the PC lattice.

In examples, the opening regions between adjacent and truncated lateral DBRs allow current injection in the PC cavity.

In examples, the apparatus for the for the PCSEL device further contains a first cladding layer on top of the PC cavity, a second cladding layer below the MQW layer, and top and bottom electrodes formed using a planarization process for co-planar radio frequency (RF) electrode design.

In examples, the PC cavity includes a cladding region surrounding the core region and comprising second nanoholes that have different sizes or spacing than the first nanoholes.

In examples, the PC lattice is also a hexagonal shape lattice.

In other examples, an apparatus for a PCSEL cluster contains a first PCSEL at a center of the PCSEL cluster. The first PCSEL includes a first PC lattice comprising first nanoholes in a first PC cavity, and a plurality of first lateral DBRs that are truncated around the first PC lattice. The apparatus also contains a plurality of second PCSELs around the center PCSEL, each second PCSEL includes a second PC lattice comprising second nanoholes in a second PC cavity and a plurality of second lateral distributed DBRs that are truncated around the second PC lattice.

In examples, the second PCSELs also form a hexagonal arrangement around the first PCSEL.

In examples, the first PCSEL and the second PCSELs are spaced from one another by a distance that allows coupling between respective beams from the first PCSEL and the second PCSELs to form a coherent combined beam output from the PCSEL cluster.

In examples, the first nanoholes and the second nanoholes of one or more second PCSELs have different spacing or sizes to provide respective beam output at a plurality of wavelengths.

In examples, the first PCSEL is configured as a PCSEL mode filter for canceling modes of the second PCSELs, and higher-order modes in the first PCSEL couple with or cancel out the modes in the second PCSELs.

In examples, one or more of the first PCSEL and the second PCSELs comprises an active material that is adjustable electrically to control an amount of side power leakage in a lateral direction from the first PC lattice or the second PC lattice. Controlling the amount of side power leakage modifies beam output pattern from the PCSEL cluster for beam steering.

In examples, the active material is in or is adjacent to at least one of the first DBRs or the second DBRs.

In examples, the first PCSEL and the second PCSELs are configured to provide beam output for different order modes and respective wavelengths at different angles for beam steering.

In other examples, a system contains a first PCSEL including a first PC lattice and a plurality of first lateral DBRs that are truncated around the first PC lattice. The system also contains a second PCSEL adjacent to the first PCSEL including a second PC lattice and a plurality of second lateral distributed DBRs that are truncated around the second PC lattice. The system further contains one or more photodiodes (PD) detectors between the first PCSEL and the second PCSEL. The PD detectors are configured to detect, over time, intensities of beam output at different angles from the first PCSEL and the second PCSEL.

The system further contains a processor configured to calculate a normalized correlation equation that indicates an amount of coherence in a beam output from the first PCSEL and the second PCSEL. The normalized correlation equation is C=1−(2×I_PD2)/(I_PD1+I_PD3) and has a range of normalized correlation values from 0 to 1, where C is a normalized correlation value, 1 indicates total coherence, and I_PD1, I_PD2 and I_PD3 are time average intensities from three respective PD detectors.

In examples, the normalized correlation value has a highest value when wavelength detuning is at a lowest level.

In examples, the system further contains an injection current controller configured to adjust an injection current in the first PCSEL and the second PCSEL based on the normalized correlation value to increase coherence in the beam output.

### BRIEF DESCRIPTION OF THE DRAWINGS

FIGS. 1A-1D show a PCSEL structure and device, in accordance with various examples.

FIG. 2A shows a field distribution of laser emissions in a PCSEL structure, in accordance with various examples.

FIG. 2B shows a relation between Q-factor and varying PC lattice periods for the PCSEL structure of FIG. 2A, in accordance with various examples.

FIG. 3 shows a PCSEL cavity structure, in accordance with various examples.

FIG. 4A shows a PCSEL cavity structure, in accordance with various examples.

FIG. 4B shows an optical field confinement of the PCSEL cavity structure of FIG. 4A, in accordance with various examples.

FIG. 5A shows a PCSEL cavity structure, in accordance with various examples.

FIG. 5B shows an optical field confinement of the PCSEL cavity structure of FIG. 4A, in accordance with various examples.

FIG. 6A shows a PCSEL cavity structure, in accordance with various examples.

FIG. 6B shows an optical field confinement of the PCSEL cavity structure of FIG. 6A, in accordance with various examples.

FIG. 7A shows a PCSEL cavity structure, in accordance with various examples.

FIG. 7B shows an optical field confinement of the PCSEL cavity structure of FIG. 7A, in accordance with various examples.

FIG. 8A shows a PCSEL cavity structure, in accordance with various examples.

FIG. 8B shows an optical field confinement of the PCSEL cavity structure of FIG. 8A, in accordance with various examples.

FIG. 8C shows a relation between Quality factor and varying periods of DBR gratings for the PCSEL structure of FIG. 8A, in accordance with various examples.

FIG. 9A shows relations between outgoing power from different directions of PCSEL structures with varying DBR gratings periods, in accordance with various examples.

FIG. 9B shows a relation between ratio of radiation intensity and the DBR gratings periods for the PCSEL structures of FIG. 9A, in accordance with various examples.

FIG. 10A show a PCSEL structure, in accordance with various examples.

FIG. 10B shows a relation between Quality factor and varying confinement periods of DBR gratings for the PCSEL structure of FIG. 10A, in accordance with various examples.

FIG. 11 shows a PCSEL cluster of PCSELs, in accordance with various examples.

FIG. 12 shows a PCSEL cluster with coherent light coupling, in accordance with various examples.

FIG. 13 shows a PCSEL cluster with incoherent light coupling, in accordance with various examples.

FIG. 14 shows a relation between light coupling and periods of DBR in a PCSEL structure, in accordance with various examples.

FIG. 15A shows an intra-cavity coherence detection system 1500, in accordance with various examples.

FIG. 15B shows field distributions between two adjacent PCSELs in the intra-cavity coherence detection system of FIG. 15A, in accordance with various examples.

FIG. 15C shows detected intensities over time at different light output angles as in the intra-cavity coherence detection system of FIG. 15A, in accordance with various examples.

FIG. 15D shows a relation between a detection correlation, as measure of coherence of light output, and wavelength detuning in the intra-cavity coherence detection system of FIG. 15A, in accordance with various examples.

### DETAILED DESCRIPTION

Further advances to solve the limitations of semiconductor laser technologies, such as limitations of distributed-feedback laser (DFB) lasers and vertical-cavity surface-emitting laser (VCSEL) technologies, contribute to secure semiconductors and microelectronic supply chains. Advances in laser technologies can also positively impact data economy, such as technologies for increasing the energy efficiency and link capability of data centers, for increasing performances of communication and sensing systems, and for providing reliable, cost effective, and higher performance LiDAR systems for autonomous vehicles.

VCSELs are relatively lower cost and scalable two-dimensional (2D) laser devices. Lower power VCSELs are used in data communication systems and consumer electronics, including smartphones and LiDAR applications. Data communication applications also use relatively higher power single mode VCSELs, for example with approximately 2.5 milliwatt (mW) of output, and with higher speed operations to meet the data transmission bit rates. VCSELs with higher power levels can have an aperture size of approximately 6 micrometer (μm) to ensure reliability of output at acceptable current density, such as approximately 10 to 20 kiloampere per centimeter square (kA/cm²). Larger size or aperture VCSELs also have multimode output with degraded spectral and beam qualities. Reducing the aperture size of VCSELs to below 5 μm can be difficult to achieve single mode output at similar power levels.

This disclosure includes examples of apparatuses, systems, and methods for laser devices based on PCSELs that have useful laser lateral confinement, coupling and structure locking capabilities. The PCSELs are surface-emitting semiconductor lasers useful for higher power single mode output and with large aperture sizes in comparison to other laser technologies. A PCSEL is a type of a photonic crystal modulated cavity structure where lasing is based on the 2D in-plane optical feedback at the band-edge of the photonic crystal. For example, PCSEL functionalities include large-area, for example from hundreds of μm to few millimeters (mm), high-brightness lasing with single mode, polarization control, and 2D beam steering. PCSELs can also provide, for a single aperture, single mode output levels such as above 10 watt (W) for continuous wave (c.w.) operation mode and 150 W for pulsed wave operation mode, with higher beam quality and brightness than other laser technologies. Examples of PCSEL devices include gallium arsenide (GaAs) based PCSELs and hybrid indium phosphide (InP)/silicon (Si) PCSELs. PCSEL modelling and simulation tools (e.g., software tools) can be used for designing various PCSEL devices, such as to increase various functionalities.

PCSELs can also operate at speeds faster than VCSELs because of a stronger vertical cavity confinement with thinner cavity thickness, for example similar to edge emitting lasers. For example, shrinking the size of PCSEL lateral cavities from hundreds of μm to tens of μm can cause high speed PCSEL emission with high power, high beam quality, and single mode operation compared to VCSELs or other laser technologies. The higher speed and higher power single mode laser output of PCSELs can surpass the limitations of VCSEL technology, including the power and speed scaling trade-offs. Because lasing in PCSELs may be based on diameters larger than approximately 30 μm, for instance to obtain large enough in-plane feedback that enables low-loss coherent lasing, PCSEL scaling to smaller aperture sizes should be addressed.

Examples of the disclosure include different optical feedback configurations in the PCSEL cavities to scale down the cavity sizes, such as down to 10 μm or less, to reach single mode, high power (e.g., in the order of tens of mW), and high speed operation (e.g., up to 50 gigahertz (GHz)). Reducing the lasing diameter to less than 10 μm by enhancing the in-plane optical feedback decreases the electrical capacitance of the PCSEL device and increases the relaxation oscillation frequency because of a higher photon density. This enables the use of PCSELs as light sources for higher speed optical communication. The examples also include the trade-offs between the operation speed and optical power for higher power and higher speed laser emitters, lateral optical feedbacks with heterostructure photonic crystal cavity and truncated DBR configurations, and vertical cavity feedbacks optimized with different types of reflectors for photon lifetime management.

The PCSEL based laser emitters can overcome the deficiencies of DFB lasers and DBR VCSELs, such as in applications for longer distance data center links, high speed free space laser communications, high speed LiDAR systems, high power photonic integrated circuits, laser based infrared countermeasures (IRCM), and compact in-band military defense systems. The provided apparatuses, systems, and methods of the disclosure can be useful for various industries, including defense industries.

Laser devices are integral components in data communications, additive manufacturing including metal and plastic printing, LiDAR, optical sensing, and other growing industries. Examples of laser devices are devices based on semiconductor technologies such as VCSELs and edge emitting lasers (EELs), which include Fabry-Perot (FP) and DFB lasers. VCSELs compromise power with low cost and high speed, and EELs may have higher speed and power at higher cost. In comparison, PCSELs can have lower cost with higher speed and power.

This PCSEL architecture can include high quality-factor (Q-factor) cavities, where the lasing state corresponds to a single, high-Q point in the PC band structure that exists above the light line. The optical mode modulated by the PCSEL cavity couples with the active materials (i.e., the multiple quantum wells, MQWs) where lasing action can be induced by emission of photons that form a light beam out of the device aperture. The PCSEL structure is similar to standard DFB laser structures, comprised of a 2D PCS layer embedded in the cladding layer.

The PCS is patterned after the initial quantum well (QW)/bottom portion of cavity growth at the first epitaxial layer, and followed by the patterned regrowth of the remaining cladding/top p-contact layers. To achieve uniform charge injection into a large area cavity (e.g., for an aperture of hundreds of μm), a p-metal pad is deposited across the whole lasing cavity aperture area, which also serves as the optical reflector. The PCSEL device is flip-chip bonded onto a sub-mount (e.g., made of Si diamond) for heat-dissipation. An N-ring contact is formed on a thin substrate, which allows light emission from the substrate side. An optical coating is also added to improve light extraction efficiency.

A sufficiently high-Q resonance can be determined for the lasing mode where the feature size of the PC can be adjusted to place the frequency of such resonance at the center of the gain spectrum. Practically, there are substantial benefits for choosing a lasing state corresponding to a resonance with zero group velocity in the plane of the PC slab, as such modes do not readily radiate out of the edges of the PCSEL device. Various PCSEL designs are focused on lasing at the momentum k-space Γ (k=0) point, where the desired photonic crystal band exhibits a critical point. Because this mode at the Γ (k=0) point is located above light line, the mode is intrinsically leaky with emission perpendicular to the in-plane direction. Lasing can be achieved at other high-symmetry points in the Brillouin zone, which allows for a measure of beam steering of for output emission.

With higher output power levels and faster operation speed, PCSELs can surpass the limitations of VCSEL technology and replace VCSELs in applications such as for high speed free space laser communications, high speed LiDAR systems, high power photonic integrated circuits, nonlinear and quantum integrated photonics. For this purpose, a modeling and simulation tool, such as PCSELSim, can be used to design PCSELs into a comprehensive platform.

High power PCSELs have been demonstrated with aperture sizes up to a few mm. In comparison, single mode VCSELs may be limited to aperture sizes of up to approximately 5 μm, and possibly up to 11 μm with a disorder-defined aperture. Shrinking the PCSEL cavity sizes down to an order of few μm can enable PCSEL devices for single mode high power emitters, without power levels of tens of mW and beyond 1 W.

Examples of applications for such PCSEL designs include high-performance long-range LiDAR, and high power and high speed extended short reach data center optical links. Because PCSELs emit light from a top surface, similar to VCSELs, PCSELs can be packaged and incorporated into printed circuit boards (PCBs) and electronic assemblies. Existing and experienced supply chain capability and capacity can also be utilized to manufacture PCSELs, similar to EELs. The PCSELs can be manufactured at various wavelengths to address a wide breadth of applications.

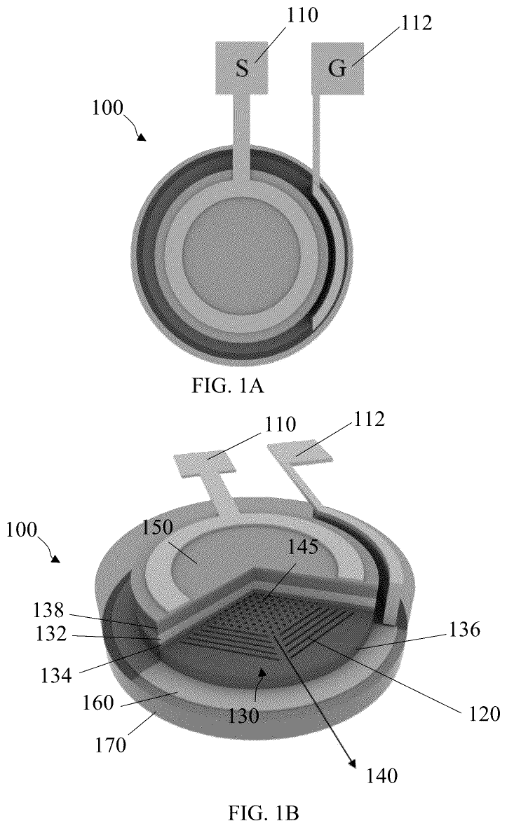

FIGS. 1A to 1D show a PCSEL structure 100 and device, in accordance with examples of this disclosure. The structure is for high speed PCSELs with high power output, where uniform charge injection is obtained by regrowth for the complete PCSEL heterostructure and formation of the top and bottom electronics. The high speed PCSEL structure 100 and device of FIGS. 1A to 1D can be flip-chip bonded for thermal management. The high speed PCSEL structure 100 in FIGS. 1A to 1D also differ from the high power PCSEL architecture. For instance, to minimize parasitic impact on high speed performance, the top and bottom electrodes 110 and 112 (labeled source (S) and ground (G), respectively) of the high speed PCSEL structures are formed using a planarization process for co-planar RF electrode design, as shown in FIG. 1A. This results in modifying the fabrication process of the high power PCSEL architecture.

The PCSEL structure in FIGS. 1A to 1D includes lateral DBR gratings, also referred to herein as lateral DBRs 120 in a PC cavity 130. The individual lateral DBRs 120 can be truncated (i.e., disconnected from each other) at the corners of the cavity sides and have a certain (e.g., equal) width. To achieve high speed operation, the PC cavity size of the PCSEL structure 100 can be reduced to a certain threshold size. For example, to shrink the cavity size down to approximately 10 μm or less, a heterostructure PC cavity 130 is formed where lateral truncated DBRs 120 are added around the cavity core 140 for the PC lattice 145 comprising nanoholes. The lateral truncated DBRs 120 are configured to provide acceptable or sufficient lateral confinement, minimize in-plane optical cavity loss, and maintain a high Q-factor cavity for low threshold lasing and high efficiency operation. The lateral truncated DBRs 120 in the PC cavity 130 are shown in FIG. 1B and FIG. 1D. In-plane cavity confinement can be designed by leveraging the symmetry dependent modal distribution in both k-space and real space, and by optimizing the truncated lateral DBRs 120 (such as the duty cycle, air slot width, etc.). FIG. 1C shows a cross section view of a high speed PCSEL structure 100, and FIG. 1D shows the PC cavity 130 design and optical mode profile 150 for the PC cavity 130 including lateral truncated DBRs 120 around a PC core region 140, according to examples of the disclosure. The PC cavity 130 includes a PC lattice of nanoholes 131 formed between an intrinsic (i) layer 134 and a positively-doped (p) layer 136. An active layer 132 is formed on top of the i layer 134. The PCSEL structure 100 further includes a negatively-doped (n) layer 138 on the layer of active layer material 132, and a n-contact layer 150 between the n layer 138 and the electrodes 110. The PCSEL structure 100 further includes a substrate 170 that serves as a sub-mount carrier/heat sink and a p contact layer 160 between the p layer 136 and the substrate 170.

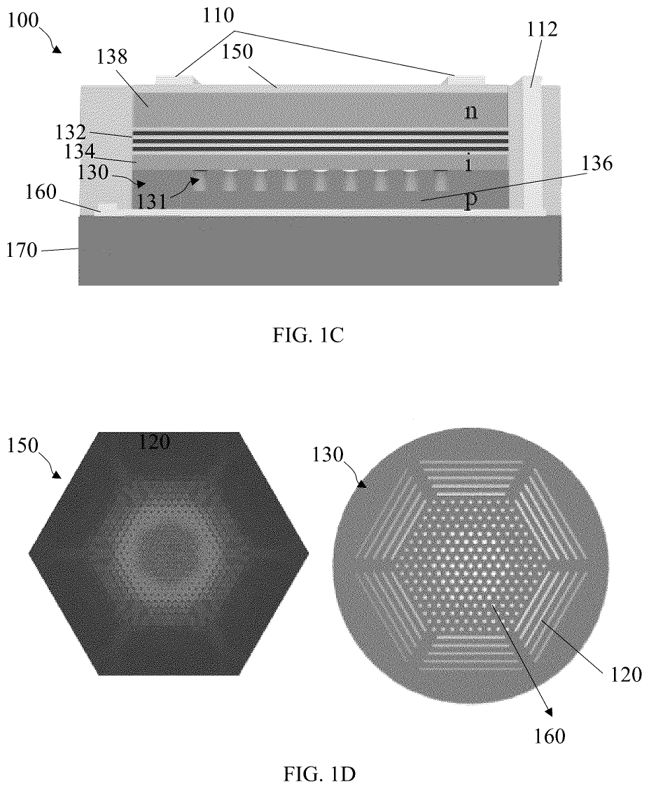

The PCSEL surface emission performance at the Γ point can be related to the in-plane PC cavity design. For high-speed operation, the impact and limits of PCSEL emitter sizes on the operation speed are useful to consider. FIGS. 2A and 2B show the lateral size impact of a PC cavity. FIG. 2A shows a field distribution of laser emissions in a PCSEL structure 200, in accordance with various examples. The laser emissions of the PCSEL structure 200 can be decomposed into the vertical and lateral directions x and z, respectively, as shown in FIG. 2A. FIG. 2A shows the optical energy field distribution in the PC region. The vertical emission 210 towards the upward or downward directions contributes to the PCSEL output. By designing suitable vertical asymmetric structures, the vertical emission 210 in one direction (upward or downward) can be increased or maximized and the extraction efficiency of the laser can be optimized. The side leakage 220 in the lateral direction, which may be useful for coupled PCSEL cavities, may not be useful for a single PCSEL emitters. For smaller PCSELs, the laser mode is squeezed in space and suffers more power leakage, resulting in a drop of the Q-factor. PCSELs with different PC lattice periods are modeled and simulated to obtain respective Q-factors. As used herein, the lattice period represents the number of rows of nanoholes around the center of the PC lattice. FIG. 2B shows a curve 230 representing a relation between Q-factor and varying PC lattice periods for the PCSEL structure 200, in accordance with various examples. FIG. 2B shows that the Q-factor drops significantly from 10,000 down to 100 when scaling the cavity size down from 40 periods to 12 periods of PC lattice, which corresponds to lateral sizes from 20 μm to 6 μm, where the lattice constant is 500 nm. To achieve higher operation speed operation, the lateral confinement of the optical field can be strengthened to maintain the Q-factor of the mode. Specifically, increasing the lateral confinement of the optical field to maintain the Q-factor of the mode can also increase the emission speed and/or output in the vertical direction of the PC cavity.

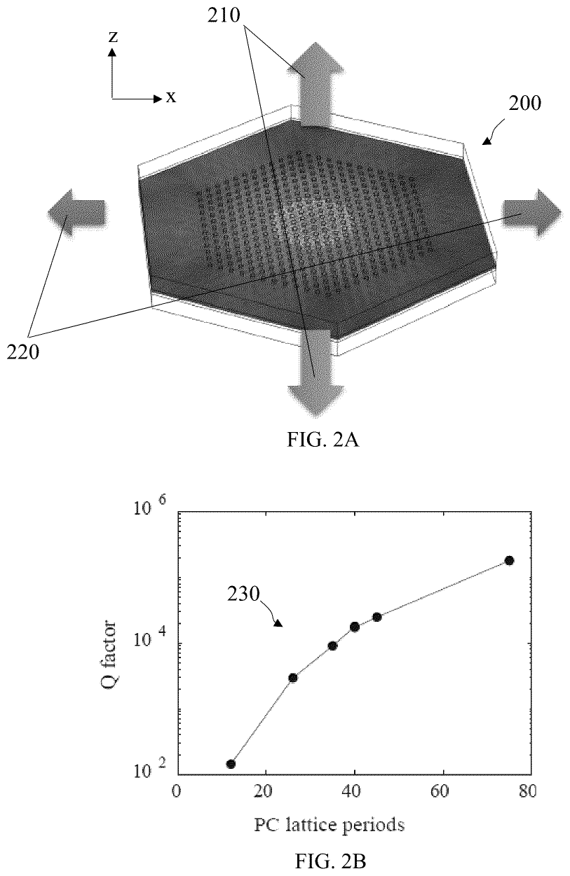

Examples of the disclosure include lateral truncated DBR structures for optical field confinement in small sized PCSEL cavities. FIG. 3 shows a PCSEL cavity structure 300, in accordance with various examples. The PC cavity structure 300 is composed of a PC cavity 310 surrounded by lateral DBRs 320. The PC cavity 310 comprises a PC core region 330 surrounded by a PC cladding region 340. For example, the PC cavity 310 is a nanohole-based cavity where the PC core region 330 and the PC cladding region 340 contain nanoholes of different sizes and/or spacing respectively. Further, the lateral DBRs 320 are truncated (i.e., disconnected from each other) and can be separate by a certain equal spacing at the corners of the cavity sides, as shown in FIG. 3.

In relation to applications in high-speed operation, efficient current injection, and reduced fabrication complexity, examples of PCSEL cavity structures, such as the PCSEL cavity structure 300, provide multiple features. For instance, the structures provide stronger mechanical support for regrowth compared to pillar cavity structures. The stronger mechanical PCSEL cavity structure 300 of the nanohole design can benefit designing structures with ultrafast speed by a suspended PC cavity 310. The lateral DBR 320 opening regions (i.e., gaps between adjacent DBRs), referred to herein as the fin structures 350, can also provide better continuity to the PC cavity 310 and improve the efficiency of current injection for in-plane current injection applications. The lateral DBRs 320 can be patterned jointly, by the same fabrication step(s) with the nanohole-based cavity PC cavity 310 of the PCSEL cavity structure 300, which reduces the fabrication complexity. The lateral DBRs 320 can also determine the active region for electron confinement. Reduced the active region volume further reduces the carrier relaxation time and increases the operation speed of the laser device.

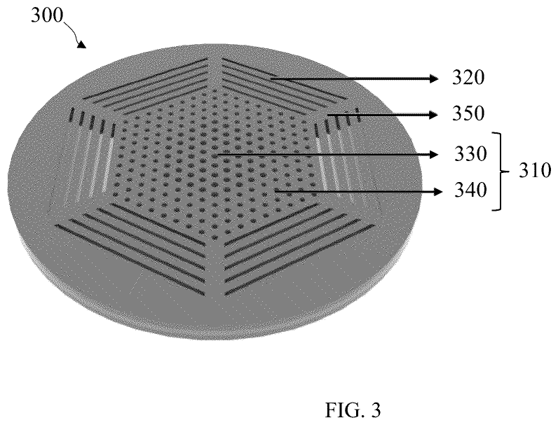

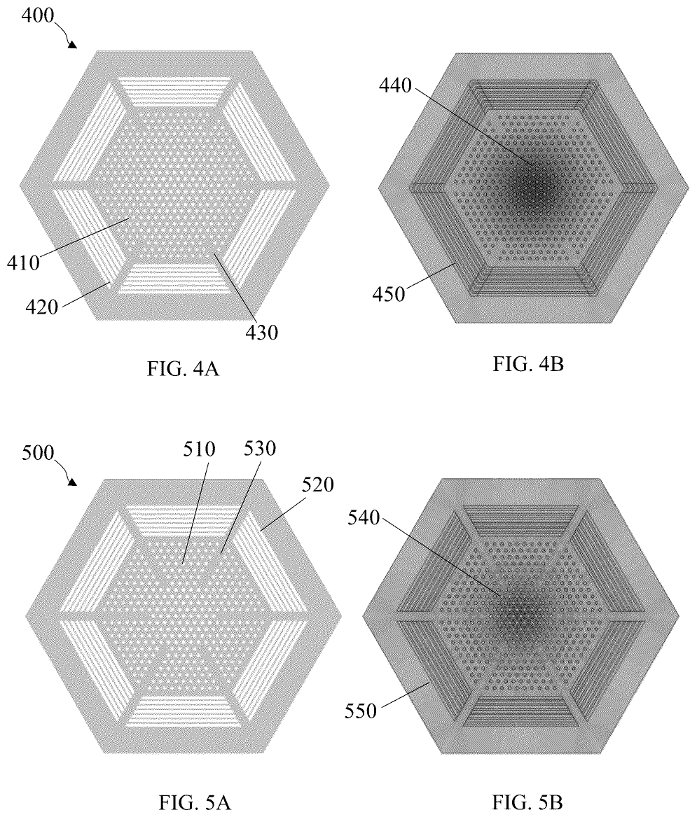

FIGS. 4A-4B and 5A-5B show examples for reducing the PCSEL active region in PCSEL structures for high speed operation according to examples of the disclosure. The PCSEL structures include a hybrid PC/lateral truncated DBR cavity, comprising a PC lattice in the core region surrounded by the lateral DBRs, which achieves strong lateral confinement for small aperture PCSELs. The truncated structure can provide strong lateral confinements and also access to electrode placement for efficient charge injection. In accordance with various examples, FIGS. 4A and 5A show PCSEL cavity structures 400 and 500, respectively, with different dimensional relations of the PC core region and the lateral DBRs. The PCSEL cavity structures 400 and 500 comprise respective PC core regions 410 and 510 with similar PC lattices with similar nanohole dimensions and spacing. The PCSEL cavity structures 400 and 500 further comprise respective lateral DBRs 420 and 530 of similar numbers and dimensions. However, the lateral DBRs 420 and 530 are truncated and spaced by respective fin structures 430 and 530. Specifically, the fin structures 530 extend deeper into the PC core region 510 in comparison to the fin structures 430 in the PC core region 410. This difference in the fin structures 430 and 530 causes the different dimensional relations of the respective PC core region and respective lateral DBRs of the PCSEL cavity structures 400 and 500.

FIGS. 4B and 5B show the respective optical field confinements of the PCSEL cavity structures 400 and 500 of FIGS. 4A and 5A, respectively, in accordance with various examples. FIGS. 4B and 5B show the respective field confinements 440 and 540 in the PC core regions 410 and 510, and also the respective field confinements 450 and 550 in the lateral DBRs 420 and 520. The PC core region 410 shows a higher field confinement 440 in comparison to the field confinement 540 in the PC core region 510, which can be caused by the less deep fin structures 430 in comparison to the fin structures 530. However, the deeper fin structures 530 can increase the charge injection in the PC core region 510 in comparison to the fin structures 430 with respect to the PC core region Various design and feature parameters are also shown in Table 1 below for the PCSEL cavity structures 400 and 500, labeled Core+Transition and Core, respectively. The parameters include the wavelength (λ), the Q-factor (Q), the ratio of radiation intensity (α_{∥}/α_{⊥}), cavity mode volume (V), active region volume (V_{act}), the optical confinement factor in the active region (T_{act}), the current threshold (Iₜₕ), and the relaxation frequency of semiconductor lasers (fᵣ). About 4 to 6 layers of MQWs are considered with total quantum well thickness of 30 nm (10% of the PC thickness).

TABLE 1

| | | | | V | V_{act} | | | |
|---|---|---|---|---|---|---|---|---|
| Structure | λ (nm) | Q | α_{∥}/α_{⊥} | (μm³) | (μm³) | Γ_{act} | Iₜₕ | fᵣ |
| Core + | 1561.39 | 1.0414E4 | 0.2328 | 1.3814 | 2.9337 | 0.08 | 0.7050 mA | 32.08 GHz |
| Transition | | | | | | | | |
| Core | 1564.00 | 1335.2 | 0.3610 | 1.1485 | 0.9055 | 0.08 | 0.2176 mA | 42.27 GHz |

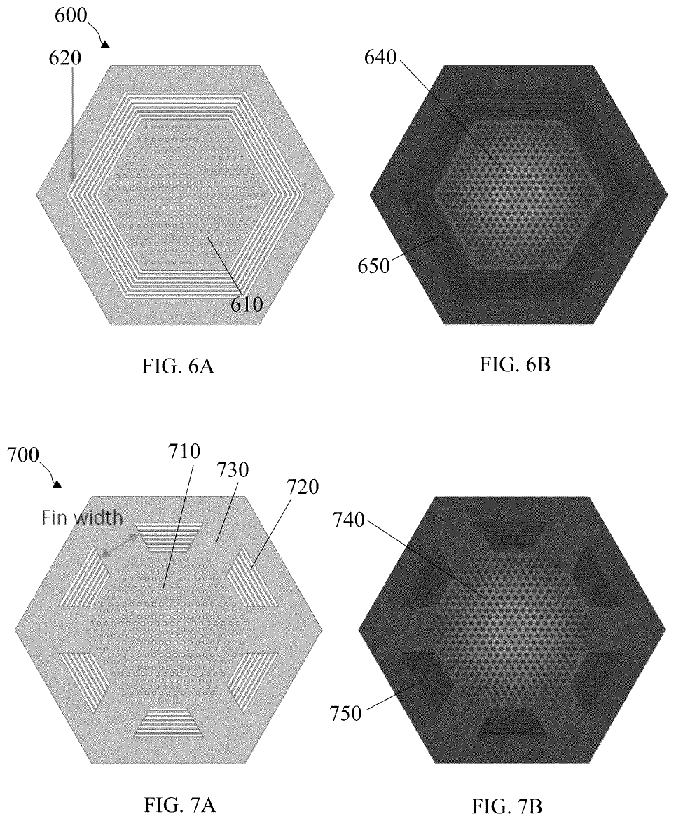

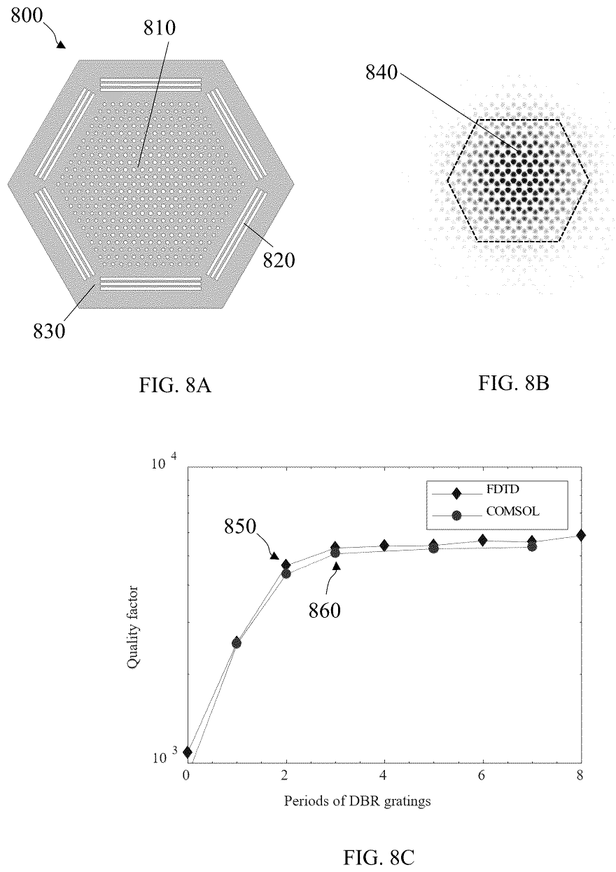

FIGS. 6A-6B and 7A-7B show the impact of the fin width in the truncated lateral DBRs of the PCSEL structures according to examples of the disclosure. In accordance with various examples, FIGS. 6A and 7A show PCSEL cavity structures 600 and 700, respectively, with different fin widths between the lateral DBRs. The PCSEL cavity structures 600 and 700 comprise respective PC cavities 610 and 710 with similar PC lattices with similar nanohole dimensions and spacing for the PC core and cladding regions. The PCSEL cavity structures 600 and 700 further comprise respective lateral DBRs 620 and 720 of similar numbers. However, the lateral DBRs 620 in the PCSEL cavity structure 600 are connected at the corners, excluding any fin structures. The lateral DBRs 720 in the PCSEL cavity structure 700 are truncated and spaced by respective fin structures 730.

FIGS. 6B and 7B show the optical field confinements of the PCSEL structures 600 and 700 of FIGS. 6A and 7A, respectively, in accordance with various examples. FIGS. 6B and 7B show the respective field confinements 640 and 740 in the PC cavities 610 and 710, and also the respective field confinements 650 and 750 in the lateral DBRs 620 and 720. The PC cavity 710 shows a higher field confinement 740 in comparison to the field confinement 640 in the PC cavity 610, which can be caused by the fin width between the truncated lateral DBRs 720 in comparison to connected DBRs 620. The fin structures 730 can also increase the charge injection in the PC cavity 710 in comparison to the PC cavity 610.

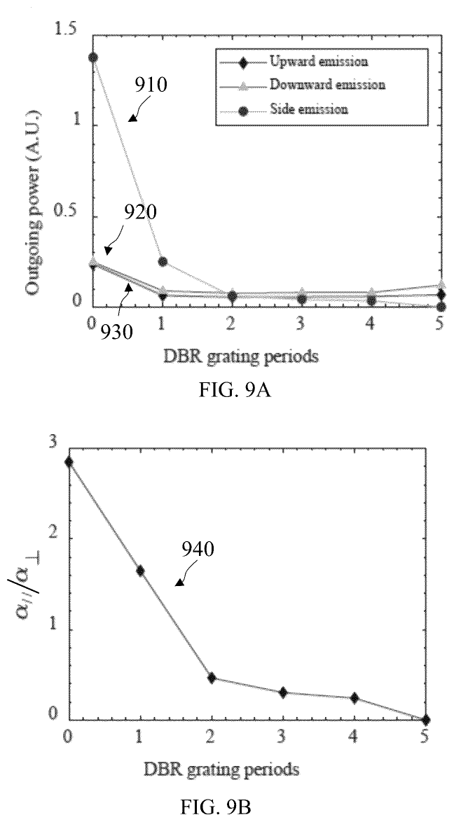

In examples, the optical confinement performance of PCSEL structures can be analyzed by different modeling tools, such as the finite-difference time-domain (FDTD) using the MEEP software and the finite element method (FEM) using the COMSOL software. FIGS. 8A to 8C show the enhancement of optical confinement with lateral DBR structures. FIG. 8A shows a PCSEL cavity structure 800, in accordance with various examples. In FIG. 8A, the PCSEL cavity structure 800 comprises lateral truncated DBR gratings 820 surrounding the PC core region of the PCSEL cavity 810, and separated by the fin structures 830. FIG. 8B shows an optical field confinement 840 of the PCSEL cavity structure 800 of FIG. 8A, and FIG. 8C shows the relation between Quality factor and varying periods of DBR gratings for the PCSEL structure 800, in accordance with various examples. As used herein, the period of the DBR grating represents the number of DBRs or reflectors in a truncated DBR grating. The relation is represented by curves 850 and 860 for data simulated using FDTD and COSMOL, respectively. The data shown in FIG. 8C is for a suspended PC slab (PCS) structure with a thickness of 300 nm, and material dielectric constant of 12. The lateral DBR regions are formed of 250 nm/160 nm alternating air/dielectric grating regions that form the lateral truncated DBR gratings 820, as illustrated in FIG. 8A. The lattice constant a is 685 nm, with an air hole filling ratio (r/a) of 0.24 in the PC core region, and r/a=0.22 in the PC cladding region.

Considering that the abrupt change in such small structures can induce the scattering loss, the PC cladding buffer region can be configured with smaller holes between the PC core region and the DBR grating regions. The cavity design has a Q-factor of about 1,000 for a PC cavity without lateral DBR confinement. With the DBR grating periods increased to above 3 periods, the Q-factor reaches a maximum of 7,000. The simulation models from the two different methods (FDTD and COSMOL) are in high agreement, as shown by curves 850 and 860, respectively, in FIG. 8C. The analysis results show that lateral DBR structures can improve the optical confinement for a PCSEL cavity with high compactness and simplicity.

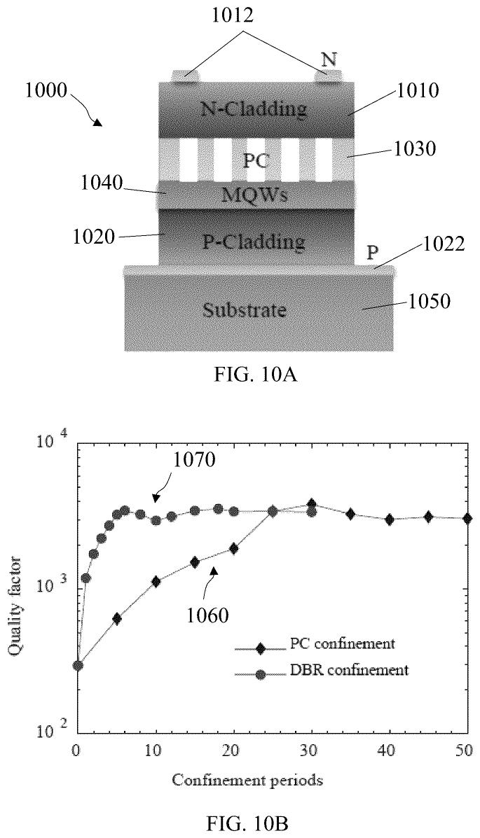

To assess the optical confinement performance of a PCSEL device, the outgoing power from the PCSEL device in the upward, downward, and side directions can be detected, as shown in FIGS. 9A and 9B. FIGS. 9A and 9B show simulation data for suspended PCSEL structures with varying DBR grating periods. The vertical emission of the structures has 50% of power output in each of the upward and downward directions. FIG. 9A shows the unnormalized outgoing power in arbitrary unit (AU) from the different directions of the structures, represented by the curve 910 for side emission, curve 920 for downward emission, and curve 930 for upward emission. FIG. 9B shows a relation between ratio of radiation intensity (α_{∥}/α_{⊥}) and the DBR gratings periods for the PCSEL structures of FIG. 9A, in accordance with various examples. Specifically, FIG. 9B shows a curve 940 representing the ratio of radiation intensity in laser emission from the in-plane to the out-of-plane directions. The data shows that without the DBR confinement, the power leakage in the horizontal directions (or side emission) is nearly three times stronger than that in the vertical direction, where the total cavity Q-factor is around 1,000.

The data also show that the power loss in the side directions drops substantially as the number of DRB gratings increases. For example, a near-total lateral optical confinement can be achieved with 5 pairs of DBRs, and the Q-factor is enhanced to around 7,000. Further optimization can be performed by the strategic design of the DBR structures. For instance, the position between the DBR and the PC cavity region can be determined to optimize the optical confinement as shown in FIGS. 4A-4B and 5A-5B and FIGS. 6A-6B and 7A-7B. By designing the separation distance between the DBR and PC core region, constructive or destructive interference can enhance or degrade the cavity Q-factor, respectively. The fin width of the truncated DBR (i.e., opening between the individual DBRs) also has impact on the power leakage. The position of the DBR openings is also a useful design factor for optimizing performance. The optical mode in the PCSEL cavity can be laterally confined in three directions for hexagonal lattice design, where the optimal position for the DBR discontinuity can be in the corner regions. In examples, PCSEL structures with optimized DBR designs can obtain a cavity Q-factor of 16,000, which is approximately a 16 times improvement for the overall cavity confinement.

In examples, a nonideal diode model is used to calculate the output power of the modeled PCSEL structures. A rate equation model is developed to estimate the laser dynamics and small signal modulation bandwidth. Table 2 below shows the impact of size scaling on the PCSEL operation bandwidth (f_{3 dB}), output power, and threshold current (Iₜₕ) obtained from the calculations. The confinement factor in the active region (Γ_{act}) is assumed to be 0.08 which corresponds to 30 nm MQWs active layers. If the Q-factor is 3,000, the bandwidth of a PCSEL with 100 μm device diameter can reach above 5 GHz and the PCSEL power can reach above 600 mW. In examples, for a 9 μm aperture device, a speed of 40 GHz can be estimated. For a 3 μm aperture device, a speed of 53.1 GHz can also be estimated. The estimated speeds may be more than twice the modulation speed reported from current and state of the art VCSEL devices.

TABLE 2

| Device | V_{act} | Output | Iₜₕ | ƒ_{3dB} |
|---|---|---|---|---|
| diameter (μm) | (μm³) | power (mW) | (mA) | (GHz) |
| 3 | 0.127 | 0.567 | 0.0996 | 54.1 |
| 10 | 1.41 | 6.372 | 1.108 | 37.5 |
| 20 | 5.65 | 25.38 | 4.434 | 20.8 |
| 50 | 35.3 | 160.02 | 27.71 | 9.19 |
| 100 | 141.4 | 637.2 | 110.8 | 5.68 |

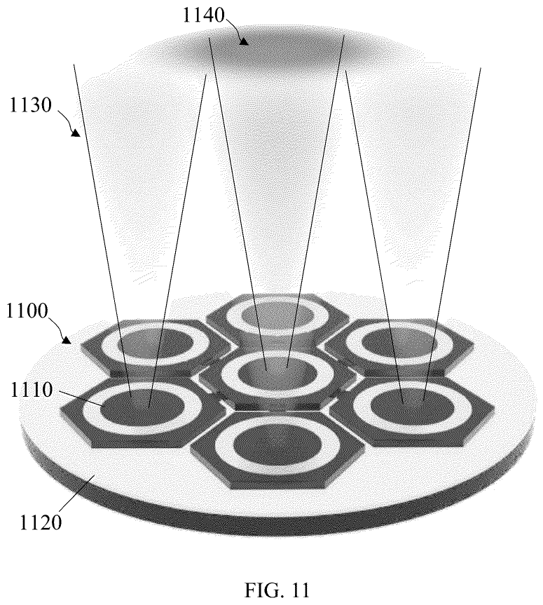

In examples, the PCSELs are implemented by an electrically injected GaAs/AlGaAs heterostructure where the small refractive index difference in the PC layer and cladding layers provides sufficient vertical optical confinement to the laser mode. the refractive index difference in the PCSEL structure may be relatively small between the PC region and the cladding layers. FIGS. 10A and 10B show examples of confinement for heterostructure PCSELs. FIG. 10A show a PCSEL structure 1000, in accordance with various examples. As shown in FIG. 10A, the top and bottom cladding layers 1010 and 1020 (labeled N-Cladding and P-Cladding), respectively, have a lower refractive index than the intrinsic PC and MQW layers in the layers 1030 and 1040, respectively, because of the larger bandgap of aluminum gallium arsenide (AlGaAs) materials in the PC and MQW layers 1030 and 1040, which provide a vertical optical confinement. The PCSEL structure 1000 also comprises a substrate 1050, N contacts 1012 on the N-Cladding layer 1010, and a P contact layer 1022 between the P-Cladding layer 1020 and the substrate 1050. FIG. 10B shows a relation between Quality factor and varying confinement periods of DBR gratings for the PCSEL structure 1000 of FIG. 10A, in accordance with various examples. Specifically, FIG. 10B shows a comparison between two different lateral confinement methods for this structure, confinement by increasing the period of the PC cladding in the PC layer (i.e., the number of circular rows of nanoholes in the PC cladding), which is represented by the curve 1060, and confinement by lateral DBR structures, which is represented by the curve 1070. The PC core area consists of 20 periods of air holes in a hexagonal lattice with a lattice constant of 450 nm. Without lateral DBR confinement, the Q-factor is 260. By adding, around the PC core, lateral DBR gratings formed of pairs of air/dielectric modulation with 300 nm/100 nm in width, respectively, the Q-factor is improved to 3,500 for 6 DBR pairs that have a 2.4 μm total width on each boundary of the PC core. The increase in the Q-factor represents the increase in lateral optical confinement in the PC cavity, which is caused by the increase in the lateral DBR grating period. In comparison, 25 periods of PC confinement air hole structures can improve the Q-factor to similar values, which extends the width to 11 μm width at each boundary. Accordingly, the DBR gratings provide stronger feedback to the cavity modes than the PC confinement, which is advantageous for high speed applications. Additional optimization can further reduce the core region size to below 10 μm and increase the 3 dB bandwidth above 40 GHz. The examples of the PCSEL structures above also support high output power. For example, 100 mW laser power with 10 GHz bandwidth can be implemented according to the calculations in Table 3.

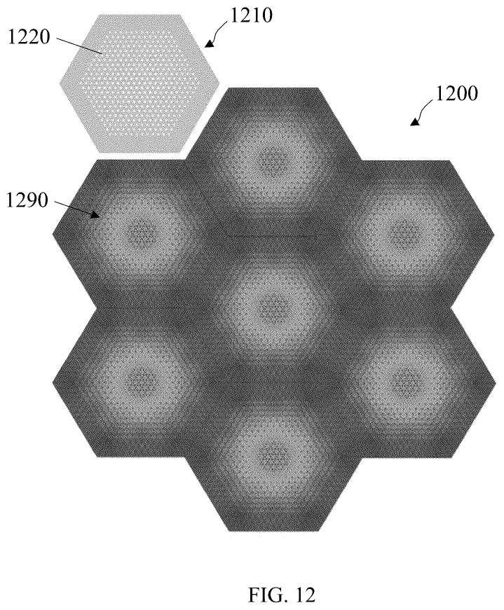

In further examples, the PCSEL structures can also be combined in a PCSEL cluster of coherently coupled PCSELs with active intra-cavity coherent beam combining (aCBC) to provide high power and high brightness output. FIG. 11 shows a PCSEL cluster 1100 of PCSELs. The PCSEL cluster 1100 comprises coherently coupled PCSELs 1110 configured to achieve high power and high brightness. The PCSEL cluster 1100 consists of a cluster of individual PCSELs 1110 with similar PCSEL structures, which can be based on the electrically pumped heterostructures described above (e.g., of FIGS. 1 to 5).

The lasing mode in the PCSELs 1110 operates at the Γ point of the PC bands and an outgoing beam is radiated from each PCSEL 1110 cavity surface with substantially low beam divergence, which can provide higher brightness. As shown in the example of FIG. 9, a hexagonal arrangement for the PCSEL cluster 1100 can be used to increase the combined laser beam power because of a higher packing efficiency compared to a square lattice. By incorporating lateral truncated DBRs for the individual PCSEL 1110 cavities, lateral cavity confinement and coupling between individual PCSEL elements can be controlled and tuned. By incorporating a detection capability, optical coherence of the output can also be monitored for actively controlling the optical coherence between the PCSELs 1110 in the cluster.

In embodiments, the PCSEL 1110 can be arranged into the PCSEL cluster 1100 on a chip 1120 to provide a coherent far field beam. The PCSELs 1110 can be spaced by a suitable distance from one another to provide a coherent beam output. The distance allows coupling between the respective beams 1130 from the individual PCSELs 1110 to form a coherent combined beam output 1140. The PCSEL cluster 1100 is a passive coherent PCSEL array that provides the coherence control in the beam output without an active control element to provide a feedback for coherence control. For example, a coherent light coupled PCSEL cluster can comprise two PCSELs in a 2-by-2 structure arrangement with a spacing of about 100 nm between the PCSELs. Such structure arrangement can provide a coherent beam combining with narrow peak wavelength at about 0.22 nm linewidth with current injection of 300 mA. In comparison, the narrow peak wavelength for the output of a single PCSEL, of the same design, is at about 0.75 nm with current injection of 200 mA. This demonstrates the potential of coherent beam combining with PCSEL clusters for power scaling applications.

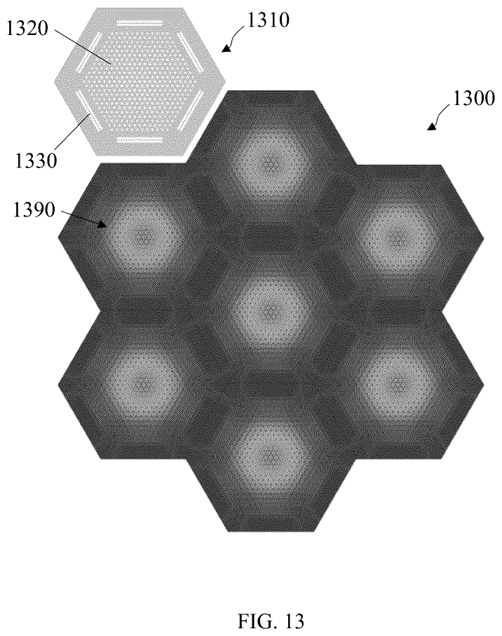

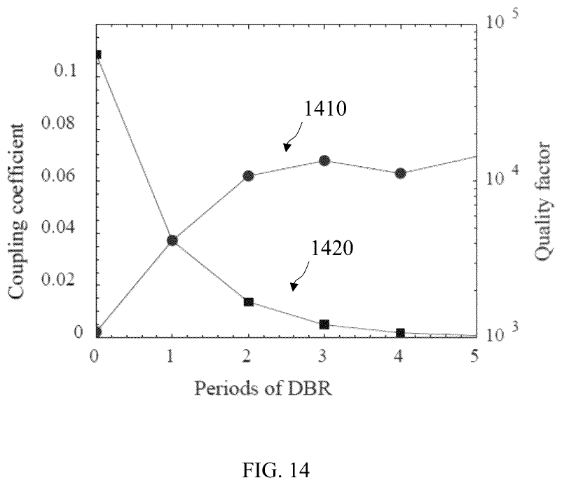

FIGS. 12 to 14 show further examples of coherent light coupling in PCSEL clusters for high power and high brightness according to examples of the disclosure. FIGS. 12 and 13 show two different PCSEL clusters based on different PCSEL designs and respective optical coherence performances. FIG. 12 shows a PCSEL cluster 1200 with coherent light coupling, also referred to herein as a coherent light coupled PCSEL (LC-PCSEL) cluster, in accordance with various examples. FIG. 13 shows a PCSEL cluster 1300 with incoherent light coupling, in accordance with various examples. The individual PCSEL structures 1210 in the first hexagonal PCSEL cluster 1200 of FIG. 12 exclude lateral DBRs around the PC cavity structure 1220. In contrast, the individual PCSEL structures 1310 in the second hexagonal PCSEL cluster 1300 includes lateral DBRs 1330 around the PC cavity structure 1320. Analyzing the light output of each of the PCSEL clusters 1200 and 1300 reveals that the individual PCSEL structures 1210 in the first hexagonal PCSEL cluster 1200 of FIG. 12 show higher optical coherence in the combined light beam output than the individual PCSEL structures 1310 in the second hexagonal PCSEL cluster 1300 of FIG. 13.

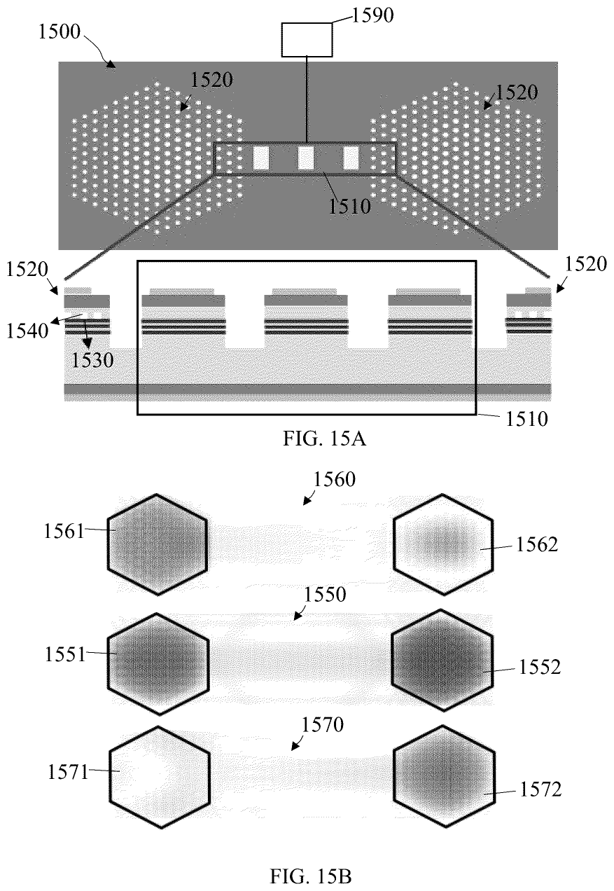

The difference in the coherence level of light output can be related to the optical confinement caused by the presence of DBRs and further to the number of periods of DBRs around the cavity structures of the PCSELs in the clusters. FIG. 14 shows a relation between light coupling coefficient and periods of DBR in a PCSEL structure, in accordance with various examples. Specifically, FIG. 14 shows a curve 1410 representing the coupling coefficient and a curve 1420 representing the Q-factor relations both in relation to the same number of DBR periods in the individual PCSEL structures of the cluster. Curves 1410 and 1420 show that as the number of DBR periods increases, the coupling between the PCSELs in the cluster decreases and the Q-factor of the output increases. As shown in FIGS. 12 and 13, adding lateral DBRs to the PC cavity increases the optical confinement 1390 of the individual PCSELs in the PCSEL cluster 1300 in comparison to the optical confinement 1200 in the PCSEL cluster 1200 and accordingly reduces optical coherence in the output.

In examples, PCSEL clusters comprising a plurality of PCSELs can be configured to operate in different resonances to provide output at a plurality of wavelengths, also referred to herein as multi-wavelength PCSEL clusters. For example, a multi-wavelength PCSEL cluster can comprise PCSELs configured to provide output at a plurality of wavelengths. The PCSEL cluster can include different groups of PCSELs, each with a different PCSEL cavity structure configured to provide output at a respective different wavelength. For example, configuring the PC lattices, in the different PCSEL cavity structures, with a different pitch (i.e., spacing) between the nanoholes can cause an output at different respective wavelengths. The output of each group of PCSELs in the cluster is combined to provide a certain intensity of output at a corresponding wavelength. The PCSELs of different groups can be placed adjacently on the surface of the cluster such that the output for each wavelength is distributed evenly across the surface.

In other examples, the PCSELs across the surface of the cluster include a similar PCSEL cavity structure that is configured to produce an output with a certain wavelength spectrum or range. For example, the wavelength spectrum can extend across the visible wavelength range (e.g., between approximately 380 to 750 nm). The wavelength range can be switched by modulating current injection in the PCCSELs.

In examples, PCSEL clusters comprising a plurality of PCSELs can be configured to provide mode filtering for a single mode operation. The modes in a PCSEL cavity can be quantized into different frequencies/wavelengths with distinct spatial field distributions, also referred to herein as orders. A PCSEL cavity structure of a main PCSEL in the cluster can be configured to operate as a PCSEL mode filter to cancel modes of other PCSELs by coupling the high-order modes in this cavity to a neighboring PCSEL cavity. The primary mode, also referred to as fundamental mode, in the neighboring cavities is designed to have the same frequency/wavelength as the higher-order modes in the main cavity to enable a gain/loss channel. By configuring the neighboring cavity gain/loss channel, the modes in the main cavity can be manipulated to function as a PCSEL mode filter for achieving a single mode operation.

For example, in a PCSEL cluster, such as the PCSEL cluster 1100, a PCSEL at the center of the cluster can be configured to function as a PCSEL mode filter and provide a single mode operation, that is an output at a certain wavelength. Specifically, the other PCSELs surrounding the center PCSEL are configured to provide orders modes (at respective wavelengths) that cancel out when combined with the same order modes of the center PCSEL, resulting in a single order mode in the output from the center PCSEL. The order modes cancel out when the respective phases of the order modes combine by destructive interference, i.e., when the respective phases are at a 180 degrees phase difference. For example, first order or higher order modes of the surrounding PCSELs can be designed to cancel out with the same order modes of the center PCSEL resulting in filtering out such modes and providing a single mode at the fundamental order of the center PCSEL.

In examples, PCSEL clusters comprising a plurality of PCSELs can be configured for beam steering by controlling optical confinement and hence power leakage in the lateral direction of the PC cavity structure. The PCT cavity structure of one or more of the PCSELs can comprise an active material that can be useful for controlling the power leakage at one of the truncated DBRs around the PC lattice. The active material can be controlled electrically, such as by the amount of current injection in the PC cavity structure. For example, the index of one of the truncated DBRs around the PC lattice can be changed electrically to control the optical confinement and thus the side power leakage from the PC lattice. In other examples, an active material placed adjacent to the DBR can be controlled electrically to control the side power leakage from the PC lattice. Changing the side power leakage also modifies the beam output pattern, which can be used for beam steering operations.

In examples, PCSEL clusters comprising a plurality of PCSELs can be configured for beam steering according to multiple order modes at respective angles. A PCSEL cluster can comprise PCSELs configured to provide output at different order modes and respective angles. The PCSEL cluster can include different groups of PCSELs, each configured to provide output at one or more order modes. The order modes and respective angles correspond to different wavelengths. Beam steering can be achieved by controlling which of the PCSELs emit light. For example, in a PCSEL cluster, such as the PCSEL cluster 1100, a PCSEL at the center of the cluster can be configured to provide 0^{th} order mode output at 0° for a first wavelength, first order modes output at respective angles for a second wavelength, and higher order modes output at other angles for a third wavelength. Further, a first group of three non-adjacent PCSELs that surround the center PCSEL can be configured to provide 0^{th} order mode output at 0° for the second wavelength, and a second group of three non-adjacent PCSELs that surround the center PCSEL can be configured to provide 0^{th} order mode output at 0° for the third wavelength. As such, beam steering from the PCSEL cluster can be achieved by switching between the center PCSEL, the first group of surrounding PCSELs, and the second group of surrounding PCSELs to vary the output angle according to the activate order mode and the selected wavelength.

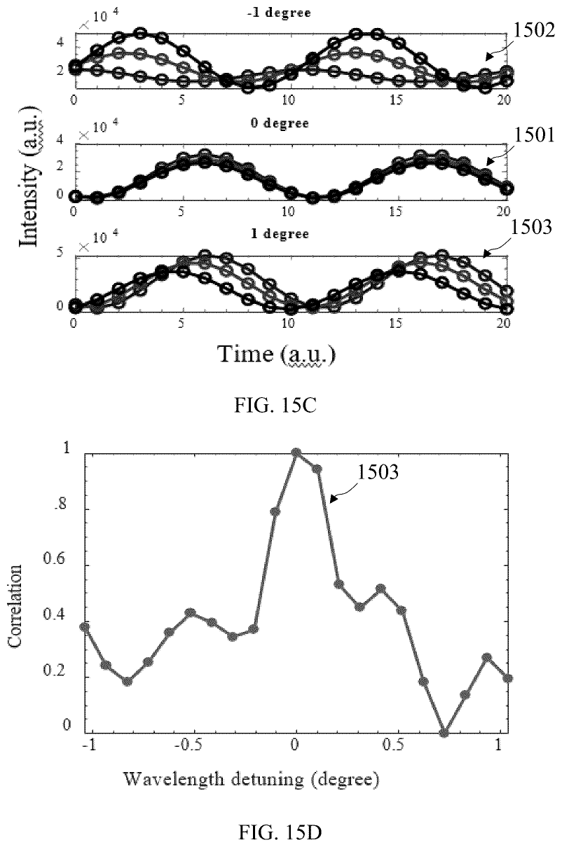

In examples, an active intra-cavity coherence detection method and system is used to obtain all-on-chip integration of a PCSEL cluster with active coherent beam combining, as shown in FIGS. 15A and 15B. FIG. 15A shows an intra-cavity coherence detection system 1500 in accordance with various examples. The method implemented using the intra-cavity coherence detection system 1500 provides an active feedback structure where PD detectors 1510 (e.g., three PD detectors) are placed between neighboring two lasers or emitters (i.e., PCSELs 1520), as shown in FIG. 15A. The PCSELS 1520 can be configured similar to the PCSEL structure 100 or 1000. The PD detectors 1510 have an equal size of 5 μm by 5 μm, which can be integrated by a fabrication process with the PCSEL mesa. The layers of the PD detectors 1510 can be fabricate with and configured similar to the layers of the PCSELS 1520 including MQWs but excluding PCs, as shown in FIG. 15A. The field intensity in the regions of the PD detectors 1510 can vary substantially when the lasers (i.e., PCSELs 1520) are operating in different wavelengths, assuming the PCSELs are operating at a single mode.

FIG. 15B shows field distributions 1560 between the two PCSELs 1520 in the intra-cavity coherence detection system 1500, in accordance with various examples. FIG. 15B shows different field distributions 1560 in the regions between the two lasers. The intra-cavity coherence detection system 1500 comprise PD detectors 1510 that receive untuned intensities 1560 and 1570 at −1 degree)(° and 1° (1° corresponds to about a 3 nm wavelength difference with 1040 nm wavelength lasers), respectively. The detected intensities 1560 at −1° include detected intensities 1561 and 1562 for the two PCSELs 1520, respectively. Similarly, the detected intensities 1570 at 1° include detected intensities 1571 and 1572 for the two PCSELs 1520, respectively. At 0°, the two PCSELs 1520 are in phase if coupled together with a suitable coupling strength, and the field inside the cavities can reach a certain peak value at the same time. Thus, the detected intensities 1550 at 0° include equal detected intensities 1551 and 1552 for the two PCSELs 1520, respectively. Clear wavelength detuning can also be detected by monitoring at the PD detectors 1510 intensities 1550 for light output from the two PCSELs 1520, respectively at the different degrees. Wavelength detuning represents an amount of deviation or spread in a beam output wavelength form a center wavelength. A wavelength detuning of 0 indicates no deviation from the center wavelength which results in higher coherence in the light beam output. The intra-cavity coherence detection system 1500 can include or be coupled to a computer or processor 1590 configured to process the detected intensities from the PD detectors. The system 1500 can also include or be coupled to an injection current controller 1595 that is configured to adjust the injection current in the adjacent PCSELs based on feedback from the controller 1590.

FIGS. 15C and 15D show a correlation of PD detected intensities for the coherence quality of light output from the device of FIG. 15A. FIG. 15C shows detected intensities (in a.u.) over time (in a.u.) at different angles of the light beam output in the intra-cavity coherence detection system 1500, in accordance with various examples. The detected intensities include intensities detected by three PD detectors 1510 at 0° represented, respectively, by three curves 1501. The detected intensities also include three curves 1502 representing intensities detected by the three PD detectors 1510, respectively, at −1°, and also three curves 1503 representing intensities detected by the three PD detectors 1510, respectively, at 1°. The computer or processor 1590 can be configured to obtain the time-averaged intensity based on the intensity detected by the PD detectors 1510. Based on the time average intensity, the amount of coherence in the beam output from the PCSELs can be calculated for each angle, by normalizing the correlation equation: C=1−(2×I_PD2)/(I_PD1+I_PD3) to a range of normalized correlation values from 0 to 1, where 1 indicates total coherence, and I_PD1, I_PD2 and I_PD3 are the time average intensities of the detected intensities by the three PD detectors 1510. This definition of coherence provides a highest value when wavelength detuning is at a lowest level (e.g., at approximately 0 wavelength detuning), as shown in FIG. 15D.

FIG. 15D shows a relation between the calculated correlation, as a measure of coherence of light beam output, and wavelength detuning (in degrees) in the intra-cavity coherence detection system 1500, in accordance with various examples. The correlation at the different degrees is represented by the curve 1504 in FIG. 15D. The coherence can be monitored by the computer or processor 1590 according to this correlation to provide feedback to the by the injection current controller 1595 for tuning the injection current for individual PCSELs to maximize or increase the correlation and hence coherence in the beam output from the PCSELs. The examples above describe using the lateral DBR confined PCSEL structure to provide passive control on the cavity Q-factor and output power, and also to allow active control of the coherent beam combining and the asymmetric operation of PCSELs.

Further examples of the disclosure are described in the documents entitled “Patent Disclosure: Laterally confinement and coupling structure”, “Patent Disclosure Laterally confined photonic crystal lasers”, and “Patent Disclosure for Coherent PCSELs”, all for which are incorporated herein by reference as if reproduced by their entirety.

What is claimed is:

1. An apparatus for a photonic crystal surface emitting laser (PCSEL) device comprising:
a photonic crystal (PC) cavity comprising:
a PC lattice comprising first nanoholes in a core region of the PC cavity;
a plurality of lateral distributed Bragg reflector gratings (DBRs) that are truncated around the PC lattice; and
opening regions between adjacent and truncated lateral DBRs around the PC lattice; and
a multiple quantum well (MQW) layer coupled to the PC cavity in a vertical direction, wherein the PCSEL device is configured to emit light in the vertical direction.

2. The apparatus of claim 1, wherein the lateral DBRs comprise a same number of DBRs, and wherein increasing the number of DBRs increases lateral optical confinement in the PC cavity.

3. The apparatus of claim 2, wherein increasing the lateral optical confinement by the lateral DBRs in the PC cavity increases emission speed and beam output power in the vertical direction of the PC cavity.

4. The apparatus of claim 1, wherein the adjacent and truncated lateral DBRs form corners around the PC lattice.

5. The apparatus of claim 1, wherein the opening regions allow current injection in the PC cavity.

6. The apparatus of claim 1, further comprising:
a first cladding layer on top of the PC cavity;
a second cladding layer below the MQW layer; and
top and bottom electrodes formed using a planarization process for co-planar radio frequency (RF) electrode design.

7. The apparatus of claim 1, wherein the PC cavity comprises a cladding region surrounding the core region and comprising second nanoholes that have different sizes or spacing than the first nanoholes.

8. The apparatus of claim 1, wherein the PC lattice is a hexagonal shape lattice.

9. An apparatus for a photonic crystal surface emitting lasers (PCSEL) cluster comprising:
a first PCSEL at a center of the PCSEL cluster and comprising:
a first photonic crystal (PC) lattice comprising first nanoholes in a first PC cavity; and
a plurality of first lateral distributed Bragg reflector gratings (DBRs) that are truncated around the first PC lattice; and
a plurality of second PCSELs around the center PCSEL and each comprising:
a second PC lattice comprising second nanoholes in a second PC cavity; and
a plurality of second lateral distributed DBRs that are truncated around the second PC lattice.

10. The apparatus of claim 9, wherein the second PCSELs form a hexagonal arrangement around the first PCSEL.

11. The apparatus of claim 9, wherein the first PCSEL and the second PCSELs are spaced from one another by a distance that allows coupling between respective beams from the first PCSEL and the second PCSELs to form a coherent combined beam output from the PCSEL cluster.

12. The apparatus of claim 9, wherein the first nanoholes and the second nanoholes of one or more second PCSELs have different spacing or sizes to provide respective beam output at a plurality of wavelengths.

13. The apparatus of claim 9, wherein the first PCSEL is configured as a PCSEL mode filter for canceling modes of the second PCSELs, and wherein higher-order modes in the first PCSEL couple with or cancel out the modes in the second PCSELs.

14. The apparatus of claim 9, wherein one or more of the first PCSEL and the second PCSELs comprises an active material, wherein the active material is adjustable electrically to control an amount of side power leakage in a lateral direction from the first PC lattice or the second PC lattice, and wherein controlling the amount of side power leakage modifies beam output pattern from the PCSEL cluster for beam steering.

15. The apparatus of claim 14, wherein the active material is in or is adjacent to at least one of the first DBRs or the second DBRs.

16. The apparatus of claim 9, wherein the first PCSEL and the second PCSELs are configured to provide beam output for different order modes and respective wavelengths at different angles for beam steering.

17. A system comprising:
a first PCSEL comprising:
a first photonic crystal (PC) lattice; and
a plurality of first lateral distributed Bragg reflector gratings (DBRs) that are truncated around the first PC lattice;
a second PCSEL adjacent to the first PCSEL and comprising:
a second PC lattice; and
a plurality of second lateral distributed DBRs that are truncated around the second PC lattice; and
one or more photodiodes (PD) detectors between the first PCSEL and the second PCSEL, wherein the PD detectors are configured to detect, over time, intensities of beam output at different angles from the first PCSEL and the second PCSEL.

18. The system of claim 17 further comprising a processor configured to calculate a normalized correlation equation that indicates an amount of coherence in a beam output from the first PCSEL and the second PCSEL, wherein the normalized correlation equation is C=1−(2×I_PD2)/(I_PD1+I_PD3) and has a range of normalized correlation values from 0 to 1, wherein C is a calculated normalized correlation value, 1 indicates total coherence, and I_PD1, I_PD2 and I_PD3 are time average intensities from three respective PD detectors.

19. The system of claim 18, wherein the calculated normalized correlation value has a highest value when wavelength detuning is at a lowest level.

20. The system of claim 18 further comprising an injection current controller configured to adjust an injection current in the first PCSEL and the second PCSEL based on the calculated normalized correlation value to increase coherence in the beam output.
